(19) United States
(12) Patent Application Publication
(10) Pub. No.: US 2024/0178279 A1
(43) Pub. Date: May 30, 2024

(54) SEMICONDUCTOR DEVICE AND METHOD OF MANUFACTURING THE SAME

(71) Applicant: SK hynix Inc., Icheon-si Gyeonggi-do (KR)

(72) Inventors: Wan Sup SHIN, Icheon-si Gyeonggi-do (KR); Yoon Ho KANG, Icheon-si Gyeonggi-do (KR); Ji Seong KIM, Icheon-si Gyeonggi-do (KR)

(73) Assignee: SK hynix Inc., Icheon-si Gyeonggi-do (KR)

(21) Appl. No.: 18/307,620

(22) Filed: Apr. 26, 2023

(30) Foreign Application Priority Data
Nov. 24, 2022 (KR) 10-2022-0158848

(51) Int. Cl. H01L 29/10; H01L 21/02; H01L 21/8234; H01L 29/49; H01L 29/68

(52) U.S. Cl. CPC H01L 29/1033; H01L 21/02362; H01L 21/823412; H01L 29/4933; H01L 29/685

(57) ABSTRACT

A semiconductor device includes a gate structure including insulating layers and conductive layers that are alternately stacked, a channel layer located in the gate structure, a silicide layer located in the channel layer, and a memory layer surrounding the channel layer. At least one of the channel layer, the silicide layer, and the memory layer includes a halogen element.

### CROSS-REFERENCE TO RELATED APPLICATION

This application claims priority under 35 U.S.C. § 119(a) to Korean Patent Application No. 10-2022-0158848 filed on Nov. 24, 2022, which is incorporated herein by reference in its entirety.

### BACKGROUND

### 1. Technical Field

Embodiments of the present disclosure relate to an electronic device, and more particularly, to a semiconductor device and a method of manufacturing the same.

### 2. Related Art

The degree of integration of a semiconductor device is mainly determined by the area occupied by a unit memory cell. Recently, as improvement in the degree of integration of a semiconductor device for forming memory cells in a single layer on a substrate reaches its limit, a three-dimensional semiconductor device for stacking memory cells on a substrate has been proposed. Furthermore, in order to improve the operational reliability of such a semiconductor device, various structures and manufacturing methods have been developed.

### SUMMARY

In an embodiment, a semiconductor device may include: a gate structure including insulating layers and conductive layers that are alternately stacked; a channel layer located in the gate structure; a silicide layer located in the channel layer; and a memory layer surrounding the channel layer, wherein at least one of the channel layer, the silicide layer, and the memory layer includes a halogen element.

In an embodiment, a semiconductor device may include: a gate structure including insulating layers and conductive layers that are alternately stacked; a channel layer located in the gate structure and including a halogen element at a first concentration; a memory layer surrounding the channel layer; and an insulating core located in the channel layer. An interface between the channel layer and the memory layer includes the halogen element at a second concentration higher than the first concentration.

In an embodiment, a method of manufacturing a semiconductor device may include: forming a stack including first material layers and second material layers that are alternately stacked; forming an opening in the stack; forming a memory layer in the opening; forming a channel layer in the memory layer; forming a passivation layer including a halogen element in the channel layer; and diffusing the halogen element into at least one of the memory layer and the channel layer from the passivation layer.

In an embodiment, a method of manufacturing a semiconductor device may include: forming a stack including first material layers and second material layers that are alternately stacked; forming an opening in the stack; forming a channel layer in the opening; forming a diffusion barrier in the channel layer; forming a protective layer in the diffusion barrier; diffusing a halogen element into the channel layer through the protective layer and the diffusion barrier; removing the protective layer; and forming an insulating core in the opening.

### BRIEF DESCRIPTION OF THE DRAWINGS

FIG. 1A to FIG. 1E are diagrams for describing a semiconductor device in accordance with an embodiment.

FIG. 2 is a graph for describing the concentration distribution of a halogen element included in a semiconductor device in accordance with an embodiment.

FIG. 3A to FIG. 3D are diagrams for describing a method of manufacturing a semiconductor device in accordance with an embodiment.

FIG. 4A to FIG. 4C are diagrams for describing a method of manufacturing a semiconductor device in accordance with an embodiment.

FIG. 5A to FIG. 5C are diagrams for describing a method of manufacturing a semiconductor device in accordance with an embodiment.

FIG. 6 is a diagram for describing a memory system in accordance with an embodiment.

### DETAILED DESCRIPTION

Various embodiments are directed to a semiconductor device having a stable structure and improved characteristics and a method of manufacturing the same.

According to the present technology, it is possible to provide a semiconductor device having a stable structure and improved reliability.

Hereafter, embodiments in accordance with the technical spirit of the present disclosure are described with reference to the accompanying drawings.

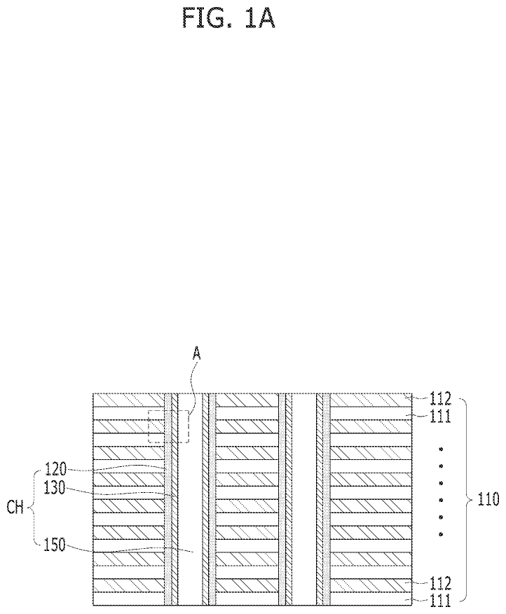

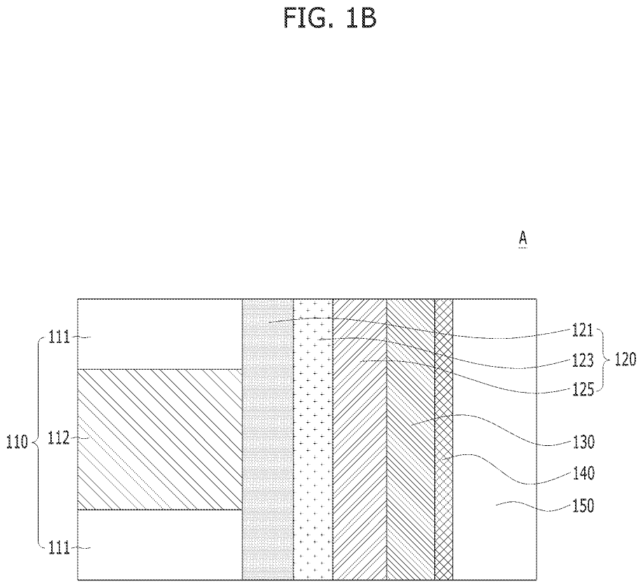

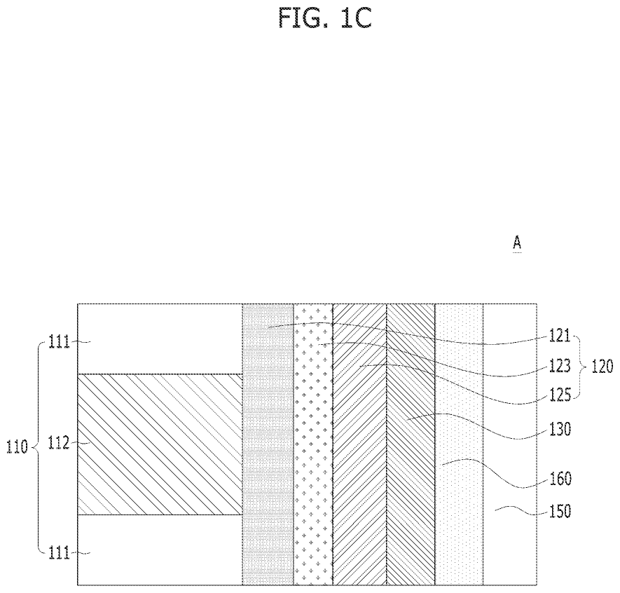

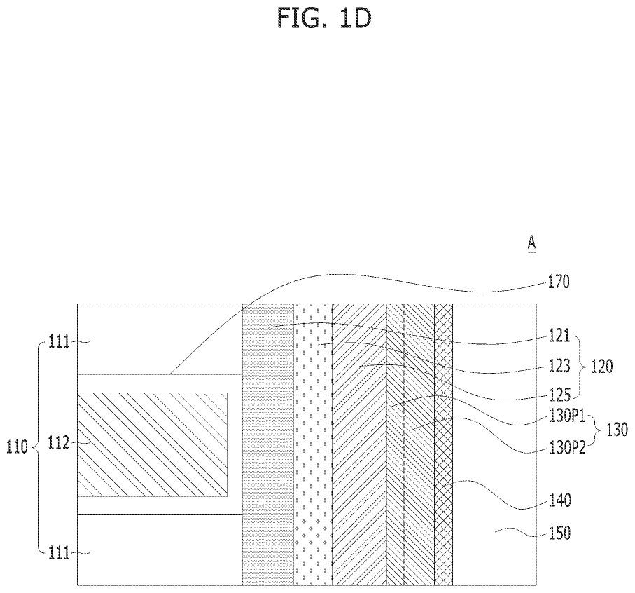

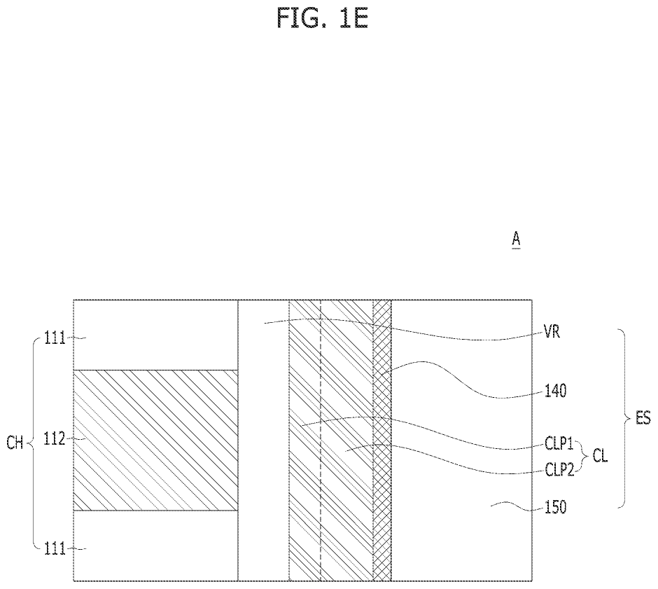

FIG. 1A to FIG. 1E are diagrams for describing a semiconductor device in accordance with an embodiment. FIG. 1B to FIG. 1E may be enlarged views of a region A in FIG. 1A.

Referring to FIG. 1A, the semiconductor device may include a gate structure 110 or channel structures CH, or a combination thereof. The gate structure 110 may include insulating layers 111 and conductive layers 112 that are alternately stacked. The conductive layers 112 may be word lines, bit lines, or select lines.

Each of the channel structures CH may be located in the gate structure 110 and may pass through the gate structure 110. Each of the channel structures CH may extend along the stacking direction of the conductive layers 112 within the gate structure 110. Each of the channel structures CH may include a channel layer 130. Each of the channel structures CH may further include a memory layer 120, a silicide layer (not illustrated), a diffusion barrier (not illustrated), or an insulating core 150, or a combination thereof.

The channel layer 130 may be located in the gate structure 110. The channel layer 130 may pass through the gate structure 110 and may extend along the stacking direction of the conductive layers 112 within the gate structure 110. The memory layer 120 may surround the channel layer 130. The insulating core 150 may be located in the channel layer 130. The channel layer 130 may include a semiconductor material such as silicon or germanium. For example, the channel layer 130 may include polysilicon. The insulating core 150 may include an insulating material such as an oxide, nitride, or air gap.

At least one of the memory layer 120, the channel layer 130, and the insulating core 150 may include a passivation material. The passivation material may include a halogen element, hydrogen, or deuterium, or a combination thereof. Examples of the passivation material may include H₂, D₂, NO, F, or Cl, or a combination thereof.

The passivation material may heal defects existing in the memory layer 120, the channel layer 130, or the insulating core 150. The passivation material may heal defects existing at an interface between the memory layer 120 and the channel layer 130 or an interface between the channel layer 130 and the insulating core 150. For example, when the layers 120, 130, and 150 each include a polycrystalline material, they may each include grain boundaries and defects may exist in the grain boundaries. Trap sites such as a dangling bond may exist at the interfaces among the layers 120, 130, and 150. The passivation material may be bonded to the grain boundaries inside the layers 120, 130, and 150 or bonded to the trap sites existing at the interfaces among the layers 120, 130, and 150 to improve layer quality and improve reliability of the semiconductor device.

Hereinafter, a case in which a halogen element is included in the semiconductor device as an example of the passivation material is described. At least one of the memory layer 120, the channel layer 130, and the insulating core 150 may include a halogen element. A halogen element may be located at at least one of the interface between the memory layer 120 and the channel layer 130 and the interface between the channel layer 130 and the insulating core 150. The halogen element may include fluorine (F) or chlorine (Cl), or a combination thereof.

Although not illustrated in the drawing, a source structure, a peripheral circuit, or the like may be located below the gate structure 110. The peripheral circuit may include transistors, capacitors, resistors, and the like.

Referring to FIG. 1B, the memory layer 120 may include a blocking layer 121, a data storage layer 123, or a tunneling layer 125, or a combination thereof. The tunneling layer 125 may surround the channel layer 130. The data storage layer 123 may surround the tunneling layer 125. The blocking layer 121 may surround the data storage layer 123. The blocking layer 121 may include an insulating material such as an oxide. The data storage layer 123 may include a floating gate, a polysilicon layer, a charge trap material, a nitride layer, a variable resistance material, or the like. The tunneling layer 125 may include an insulating material such as an oxide.

A silicide layer 140 may be located in the channel layer 130. The insulating core 150 may be located in the silicide layer 140. In other words, the silicide layer 140 may be located between the channel layer 130 and the insulating core 150. The silicide layer 140 may be a layer remaining during a manufacturing process of the semiconductor device. For example, the silicide layer 140 may be a layer formed by a reaction between the channel layer 130 and a protective layer (not illustrated) during the manufacturing process. The silicide layer 140 may include metal silicide or the like. For example, the silicide layer 140 may include tungsten silicide (WSiₓ) or titanium silicide (TiSiₓ).

At least one of the channel layer 130, the memory layer 120, and the silicide layer 140 may include a halogen element. At least one of the blocking layer 121, the data storage layer 123, and the tunneling layer 125 may include a halogen element. A halogen element may be located at the interface between the memory layer 120 and the channel layer 130. A halogen element may be located at an interface between the channel layer 130 and the silicide layer 140.

Referring to FIG. 1C, the semiconductor device may further include a diffusion barrier 160. The diffusion barrier 160 may be located between the channel layer 130 and the insulating core 150. The diffusion barrier 160 is a layer remaining during the manufacturing process of the semiconductor device, and may prevent or reduce diffusion of metal into the channel layer 130. The diffusion barrier 160 may include a halogen element. The diffusion barrier 160 may include an insulating material such as an oxide or nitride. For example, the anti-diffusion layer 160 may include SiO₂, Si₃N₄, or the like.

Referring to FIG. 1D, the channel layer 130 may include a first portion 130P1 and a second portion 130P2. The first portion 130P1 may be located closer to the memory layer 120 than the second portion 130P2. The second portion 130P2 may be spaced farther apart from the memory layer 120 as compared to the first portion 130P1. For example, the second portion 130P2 may be located closer to the silicide layer 140 than the first portion 130P1. As described above with reference to FIG. 1C, when the semiconductor device includes the diffusion barrier 160 instead of the silicide layer 140, the second portion 130P2 may be located closer to the diffusion barrier 160 than the first portion 130P1.

The first portion 130P1 and the second portion 130P2 may be different in their concentration of the halogen element from each other. The first portion 130P1 and the second portion 130P2 may have different concentration gradients of halogen elements. As the first portion 130P1 becomes closer to the memory layer 120, the concentration of the halogen element of the first portion 130P1 may increase. For example, as the first portion 130P1 becomes closer to the interface between the channel layer 130 and the memory layer 120, the concentration of the halogen element of the first portion 130P1 may increase. As the second portion 130P2 becomes closer to the silicide layer 140, the concentration of the halogen element of the second portion 130P2 may increase. For example, as the second portion 130P2 becomes closer to the interface between the channel layer 130 and the silicide layer 140, the concentration of the halogen element of the second portion 130P2 may increase. This is because the interface is a boundary between different layers and may include many defects because it is unstable. The interface between the memory layer 120 and the channel layer 130 and the interface between the channel layer 130 and the silicide layer 140 may each require a large amount of halogen elements to heal defects. Accordingly, the concentration of the halogen element in interfaces with relatively many defects may be relatively high.

The semiconductor device may further include a liner layer 170. The liner layer 170 may be located between the conductive layers 112 and the blocking layer 121 and may extend along sidewalls of the conductive layers 112. The liner layer 170 may include a high-k material. The liner layer 170 may include a halogen element.

The liner layer 170 may be a blocking layer or a memory layer. The blocking layer may include a high-k material, and the memory layer may include at least one of a blocking layer, a data storage layer, and a tunneling layer. The liner layer 170 may also be applied to FIG. 1A to FIG. 1C. For example, the liner layer 170 may be located between the conductive layers 112 and the blocking layer 121 in FIG. 1A to FIG. 1C, and may extend along the sidewalls of the conductive layers 112.

Referring to FIG. 1E, the semiconductor device may also include electrode structures ES instead of the channel structures CH. Each of the electrode structures ES may include a variable resistance layer VR. Each of the electrode structures ES may further include the silicide layer 140 or the insulating core 150, or a combination thereof.

The gate structure 110 may alternately include the insulating layers 111 and first conductive lines 112A. The first conductive lines 112A may each include a conductive material such as polysilicon or metal. The first conductive lines 112A may be word lines, bit lines, or select lines.

A second conductive line CL may be located in the gate structure 110 and may pass through the gate structure 110. The second conductive line CL may extend through the gate structure 110. The insulating core 150 may be located in the second conductive line CL. The second conductive line CL may include a first portion CLP1 and a second portion CLP2. The first portion CLP1 may be located closer to the variable resistance layer VR than the second portion CLP2. The second portion CLP2 may be spaced apart from the variable resistance layer VR compared to the first portion CLP1. The first part CLP1 and the second part CLP2 may be different in their concentration of a halogen element. As the first part CLP1 becomes closer to the variable resistance layer VR, the concentration of the halogen element of the first part CLP1 may increase. As the second portion CLP2 becomes closer to the insulating core 150, the concentration of the halogen element of the second portion CLP2 may increase.

The second conductive line CL may include a conductive material such as polysilicon or metal. The second conductive line CL may be a bit line, a word line, or a select line. When the first conductive lines 112A are word lines, the second conductive line CL may be a bit line.

The variable resistance layer VR may be located between the first conductive lines 112A and the second conductive line CL. The variable resistance layer VR may include a phase change material and chalcogenide. The variable resistance layer VR may be phase-changed according to a program operation. The variable resistance layer VR may include a variable resistance material whose resistance changes without a phase change, and may include a chalcogenide-based material. The variable resistance layer VR may have an amorphous state and might not be changed to a crystalline state during the program operation.

The silicide layer 140 may be located in the second conductive line CL. The silicide layer 140 may be a layer remaining during the manufacturing process. A diffusion barrier 160 may also be located instead of the silicide layer 140. The diffusion barrier 160 may prevent or reduce diffusion of metal into the variable resistance layer VR during the manufacturing process.

Although not illustrated in the drawing, a protective layer may be located between the second conductive line CL and the insulating core 150. The protective layer may prevent or reduce diffusion of metal into the variable resistance layer VR and the second conductive line CL. The remaining protective layer may be used as an electrode together with the second conductive line CL.

At least one of the variable resistance layer VR, the second conductive line CL, the silicide layer 140, and the diffusion barrier may include a halogen element. The halogen element may include fluorine (F) or chlorine (Cl), or a combination thereof.

In present specification, an example in which the semiconductor device includes the silicide layer 140 and the insulating core 150 has been described; however, at least one of the silicide layer 140 and the insulating core 150 might not be included.

According to the structure described above, the channel layer 130 and the memory layer 120 may each include a halogen element, and the halogen element may be located at an interface between the channel layer 130 and the memory layer 120. Accordingly, defects existing in the channel layer 130 or the memory layer 120 or defects existing at the interface between the channel layer 130 and the memory layer 120 may be healed by the halogen element.

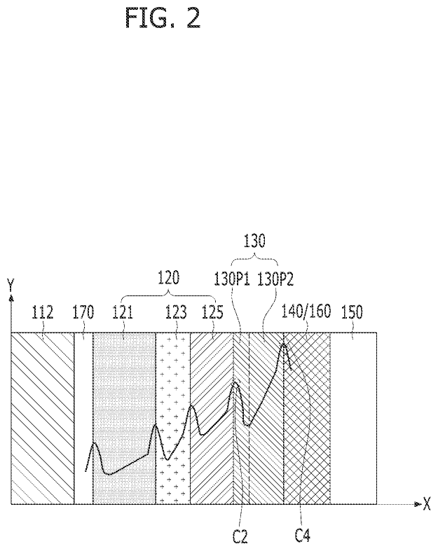

FIG. 2 is a graph for describing the concentration distribution of the halogen element included in the semiconductor device in accordance with an embodiment. Hereinafter, content previously described is not repeated.

Referring back to FIG. 1A to FIG. 1D, the semiconductor device may include the gate structure 110, the liner layer 170, the memory layer 120, the channel layer 130, the silicide layer 140, the diffusion barrier 160, or the insulating core 150, or a combination thereof. The memory layer 120 may include the blocking layer 121, the data storage layer 123, and the tunneling layer 125. The layers illustrated in FIG. 2 are layers corresponding to the components constituting the semiconductor device described with reference to FIG. 1A to FIG. 1D, and may be simplified representations of some layers of the components. An x-axis may mean relative position and thickness of each layer, and a y-axis may mean the concentration of the halogen element.

Referring to FIG. 2, a difference in the concentration of the halogen element may exist among the conductive layer 112, the liner layer 170, the memory layer 120, the channel layer 130, the silicide layer 140, the diffusion barrier 160, and the insulating core 150. The concentration may mean a minimum concentration, a maximum concentration, or an average concentration of the halogen elements included in the layers 112, 170, 120, 130, 140, 160, and 150.

The concentration of the halogen elements included in the layers 112, 170, 120, 130, 140, 160, and 150 may be changed according to the diffusion direction of the halogen elements during the manufacturing process. For example, when the halogen element is diffused from the channel layer 130 toward the memory layer 120, the channel layer 130 or a layer adjacent to the channel layer 130 may include a higher concentration of a halogen element than a layer spaced apart from the channel layer 130.

The difference in the concentration of the halogen element may exist in the insides of the layers 112, 170, 120, 130, 140, 160, and 150 and between interfaces thereof. The interfaces may include an interface between the liner layer 170 and the blocking layer 121, an interface between the blocking layer 121 and the data storage layer 123, an interface between the data storage layer 123 and the tunneling layer 125, an interface between the tunneling layer 125 and the channel layer 130, an interface between the channel layer 130 and the silicide layer 140, an interface between the channel layer 130 and the diffusion barrier 160, and an interface between the channel layer 130 and the insulating core 150. This is because the interface is a boundary between different layers and may include more defects than the insides of the layers because it is unstable. In other words, because the interfaces among the layers 112, 170, 120, 130, 140, 160, and 150 may each require more halogen elements than the insides of the layers to heal defects, a halogen element at a relatively high concentration may be located at the interfaces among the layers.

At least one of the liner layer 170, the memory layer 120, the channel layer 130, the silicide layer 140, and the diffusion barrier 160 may include a halogen element. The channel layer 130 may include a halogen element at a first concentration. The first concentration may mean a minimum concentration, a maximum concentration, or an average concentration of the halogen elements. The interface between the channel layer 130 and the memory layer 120 may include a halogen element at a second concentration C2. The first concentration and the second concentration C2 may be substantially the same as or different from each other. For example, the second concentration C2 may be higher than the first concentration.

The channel layer 130 may include the first portion 130P1 whose concentration of the halogen element increases as it becomes closer to the memory layer 120. The channel layer 130 may include the second portion 130P2 whose concentration of the halogen element increases as it becomes closer to the silicide layer 140. As described above with reference to FIG. 1C, when the semiconductor device includes the diffusion barrier 160 instead of the silicide layer 140, the concentration of the halogen element of the second portion 130P2 may increase as it becomes closer to the diffusion barrier 160.

The tunneling layer 125 may include a halogen element at a third concentration. The interface between the tunneling layer 125 and the channel layer 130 may include a halogen element at the second concentration C2 higher than the third concentration. The interface between the channel layer 130 and the silicide layer 140 may include a halogen element at a fourth concentration C4. The fourth concentration C4 may be substantially the same as or different from the second concentration C2. For example, the fourth concentration C4 may be higher than the second concentration C2. As described above with reference to FIG. 1C, when the semiconductor device includes the diffusion barrier 160 instead of the silicide layer 140, the interface between the channel layer 130 and the diffusion barrier 160 may include a halogen element at the fourth concentration C4.

Referring to FIG. 1E, the semiconductor device may include the gate structure 110 including the insulating layers 111 and the first conductive lines 112A that are alternately stacked, the variable resistance layer VR, the second conductive line CL, the silicide layer 140, the diffusion barrier, or the insulating core 150, or a combination thereof. Among the layers illustrated in FIG. 2, the conductive layer 112 may correspond to the first conductive lines 112A. The memory layer 120 may correspond to the variable resistance layer VR. The channel layer 130 may correspond to the second conductive line CL.

A difference in the concentration of a halogen element may exist among the first conductive line 112A, the variable resistance layer VR, the second conductive line CL, the silicide layer 140, and the insulating core 150. The difference in the concentration of the halogen element may exist in the insides of the layers 112A, VR, CL, 140 and 150 and between interfaces thereof. At least one of the variable resistance layer VR, the second conductive line CL, and the silicide layer 140 may include a halogen element. The second conductive line CL may include a halogen element at a first concentration. The interface between the second conductive line CL and the variable resistance layer VR may include a halogen element at a second concentration higher than the first concentration.

According to the structure described above, the insides of the layers 170, 120, 130, 140, 160, and 150 and the interfaces among the layers 170, 120, 130, 140, 160, and 150 may have halogen elements at different concentrations. The interfaces among the layers may each include a higher concentration of a halogen element than the insides of the layers, and defects in the insides of the layers and the interfaces among the layers may be healed by the halogen element.

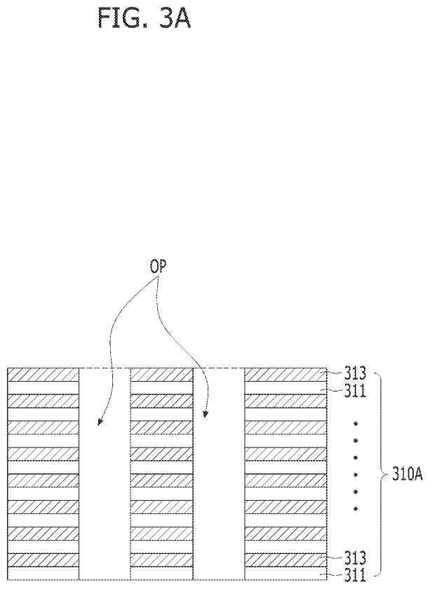

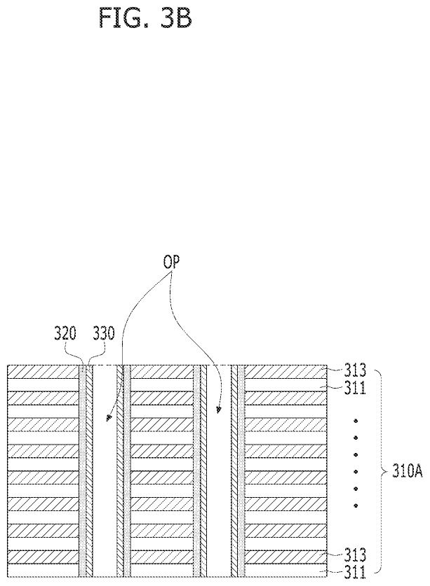

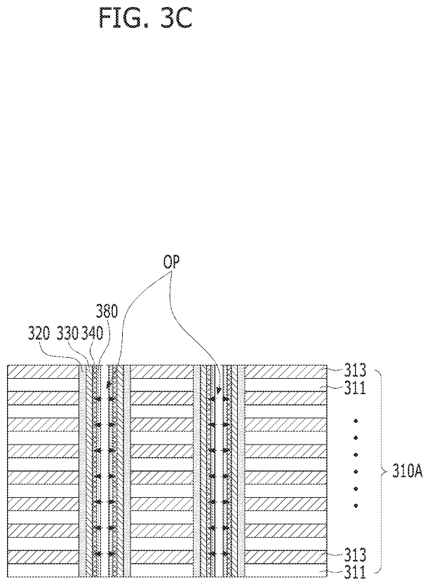

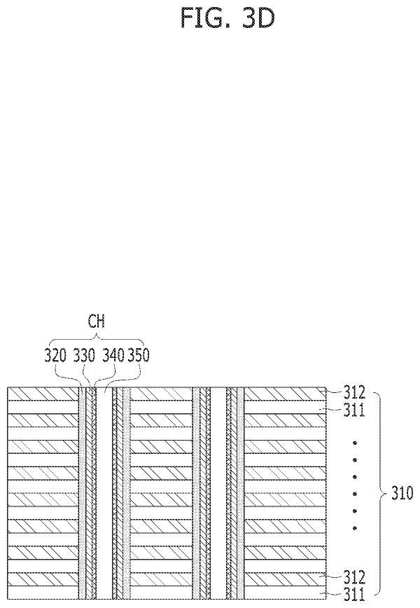

FIG. 3A to FIG. 3D are diagrams for describing a method of manufacturing a semiconductor device in accordance with an embodiment. Hereinafter, content previously described is not repeated.

Referring to FIG. 3A, a stack 310A may be formed. The stack 310A may include first material layers 311 and second material layers 313 that are alternately stacked. The first material layers 311 may each include a material having a higher etching selectivity than the second material layers 313. For example, the first material layers 311 may each include an insulating material such as an oxide, and the second material layers 313 may each include a sacrificial material such as nitride. As another example, the first material layers 311 may each include an insulating material such as an oxide, and the second material layers 313 may each include a conductive material such as polysilicon, tungsten, or molybdenum.

Subsequently, at least one opening OP may be formed in the stack 310A. The openings OP may pass through the first material layers 311 and the second material layers 313 that are alternately stacked.

Before the stack 310A is formed, a source structure or a peripheral circuit may be formed. The peripheral circuit may include transistors, capacitors, or resistors.

Referring to FIG. 3B, a memory layer 320 may be formed. For example, the memory layer 320 may be formed in the opening OP. The memory layer 320 may include at least one of a blocking layer, a data storage layer, and a tunneling layer. Subsequently, a channel layer 330 may be formed in the memory layer 320. The data storage layer may include a floating gate, a polysilicon layer, a charge trap material, a nitride layer, a variable resistance material, or the like. The channel layer 330 may include a semiconductor material such as silicon or germanium. For example, the channel layer 330 may include polysilicon. The second conductive line CL described above with reference to FIG. 1E may be formed instead of the channel layer 330. The second conductive line CL may be a word line, a bit line, or a select line. The second conductive line CL may include a conductive material such as polysilicon or metal.

When the memory layer 320 or the channel layer 330 includes a polycrystalline material, it may include grain boundaries, and defects may exist in the grain boundaries. A trap site such as a dangling bond may exist at an interface between the memory layer 320 and the channel layer 330.

Referring to FIG. 3C, a protective layer 380 may be formed. For example, the protective layer 380 including metal may be formed in the channel layer 330. The protective layer 380 may prevent or reduce damage to the memory layer 320 or the channel layer 330 in a passivation process to be described below. For example, the protective layer 380 may prevent or reduce etching of the memory layer 320 or the channel layer 330 in the passivation process. The protective layer 380 may include metal such as titanium or tungsten, metal nitride, or a combination thereof. For example, the protective layer 380 may include Ti, TiN, WN, or W, or a combination thereof. The protective layer 380 may be a single layer or a multiplayer. For example, the protective layer 380 may be a single layer including metal or metal nitride, or a multilayer including a combination thereof.

A silicide layer 340 may be formed at an interface between the channel layer 330 and the protective layer 380. The channel layer 330 and the protective layer 380 may react at the interface according to physical properties of the channel layer 330 and the protective layer 380. For example, when the channel layer 330 includes polysilicon and the protective layer 380 includes metal, the silicide layer 340 may be formed at the interface between the channel layer 330 and the protective layer 380 by a reaction between silicon and the metal. The silicide layer 340 may include metal silicide or the like. For example, the silicide layer 340 may include tungsten silicide (WSiₓ) or titanium silicide (TiSiₓ).

The present specification has described a case in which the silicide layer 340 is formed before the passivation process; however, the silicide layer 340 might not be formed or the formation time of the silicide layer 340 may be changed. For example, the silicide layer 340 might not be formed before the passivation process, and may be formed during the passivation process. As another example, the silicide layer 340 may be formed before the passivation process, and may be additionally formed during the passivation process.

Subsequently, the passivation process may be performed. For example, a passivation material may be supplied through the opening OP, and may be diffused into the channel layer 330 or the memory layer 320 through the protective layer 380 and the silicide layer 340. The passivation material may be supplied in the form of a passivation gas. The passivation material may include a halogen element, hydrogen, or deuterium, or a combination thereof. Hereinafter, a case in which a halogen element as an example of the passivation material is included in a semiconductor device is described. For example, a halogen element may be diffused through the protective layer 380 and the silicide layer 340. The halogen element may include fluorine (F) or chlorine (Cl), or a combination thereof.

The halogen element may be diffused into at least one of the protective layer 380, the channel layer 330, and the memory layer 320. The halogen element may be diffused into at least one of the protective layer 380, the channel layer 330, and the memory layer 320 through the opening OP by using a gas including the halogen element. For example, when the passivation material includes fluorine (F) as the halogen element, the halogen element may be diffused through a gas including WF₆. As another example, when the passivation material includes chlorine (Cl) as the halogen element, the halogen element may be diffused through a gas including SiH₂Cl₂, SiCl₄, Si₂Cl₆, or TiCl₄. Accordingly, the channel layer 330, the memory layer 320, or the interface between the memory layer 320 and the channel layer 330 may include the halogen element.

The memory layer 320, the channel layer 330, and the interface between the memory layer 320 and the channel layer 330 may have halogen elements at substantially the same concentration or different concentrations. For example, the channel layer 330 may include a halogen element at a first concentration, and the interface between the memory layer 320 and the channel layer 330 may include a halogen element at a second concentration. The second concentration may be substantially the same as or different from the first concentration. For example, the second concentration may be higher than the first concentration.

The halogen element may heal defects existing in the memory layer 320, the channel layer 330, or the interface between the memory layer 320 and the channel layer 330. For example, the halogen element may be diffused into the memory layer 320 and the channel layer 330 and be bonded to grain boundaries inside the memory layer 320 or the channel layer 330 to heal defects. The halogen element may also be bonded to a trap site existing at the interface between the memory layer 320 and the channel layer 330 to improve layer quality and reliability of the semiconductor device.

In the passivation process, the memory layer 320 or the channel layer 330 may be protected by the protective layer 380. For example, the protective layer 380 may prevent or reduce etching of the channel layer 330 or the memory layer 320 caused by a passivation gas.

Heat treatment may be performed simultaneously with or after the passivation process. When the heat treatment is performed, a halogen element may be diffused more rapidly or a greater amount of a halogen element may be diffused into the channel layer 330 and the memory layer 320. Furthermore, the silicide layer 340 may be formed more rapidly or with a greater thickness.

Referring to FIG. 3D, an insulating core 350 may be formed. First, the protective layer 380 may be removed. For example, the protective layer 380 may be removed through a cleaning process. The cleaning process may be a process using a sulfur peroxide mixture (SPM). At this time, the silicide layer 340 may be removed or may remain without being removed. Subsequently, the insulating core 350 may be formed in the opening OP. For example, the insulating core 350 may be formed in the silicide layer 340. The insulating core 350 may include an insulating material such as an oxide, nitride, or air gap.

Subsequently, the second material layers 313 may be replaced with third material layers 312. When the second material layers 313 are sacrificial layers, slits passing through the stack 310A may be formed, and the second material layers 313 may be removed through the slits. Subsequently, the third material layers 312 may be formed in regions where the second material layers 313 are removed. Before the third material layers 312 are formed, the liner layer 170 described with reference to FIG. 1C may be formed in the regions where the second material layers 313 are removed. The third material layers 312 may be conductive layers and may each include a conductive material such as polysilicon, tungsten, or molybdenum. When the second material layers 313 are conductive layers, the third material layers 312 may be formed by performing a process for reducing resistance of the second material layers 313, such as a silicidation process. Thus, a gate structure 310 including the first material layers 311 and the third material layers 312 that are alternately stacked may be formed.

In the drawing, only an example in which the silicide layer 340 remains has been described; however, the present disclosure is not limited thereto, the silicide layer 340 may also be removed when the protective layer 380 is removed, and the insulation core 350 may be formed in the channel layer 330.

According to the process described above, a halogen element may be diffused into the channel layer 330, the interface between the channel layer 330 and the memory layer 320, and the memory layer 320. The halogen element may heal defects inside the channel layer 330 and the memory layer 320, and may heal defects at the interface between the channel layer 330 and the memory layer 320.

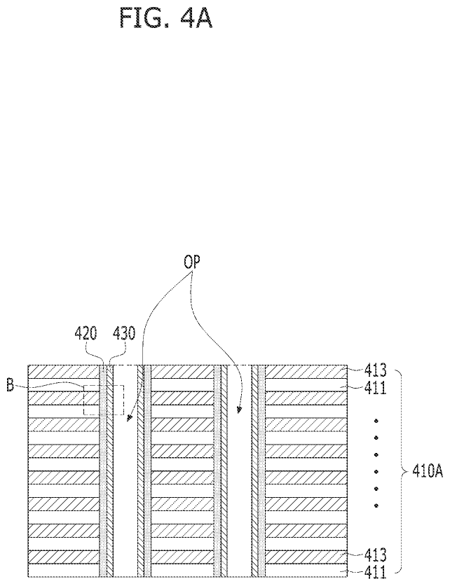

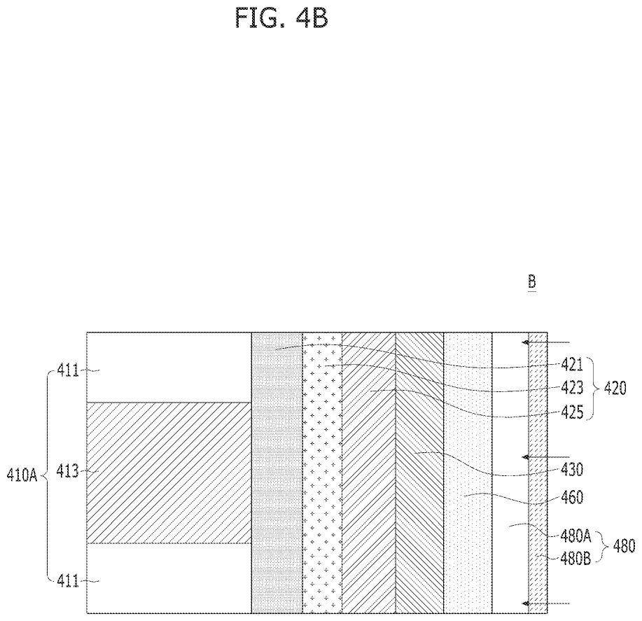

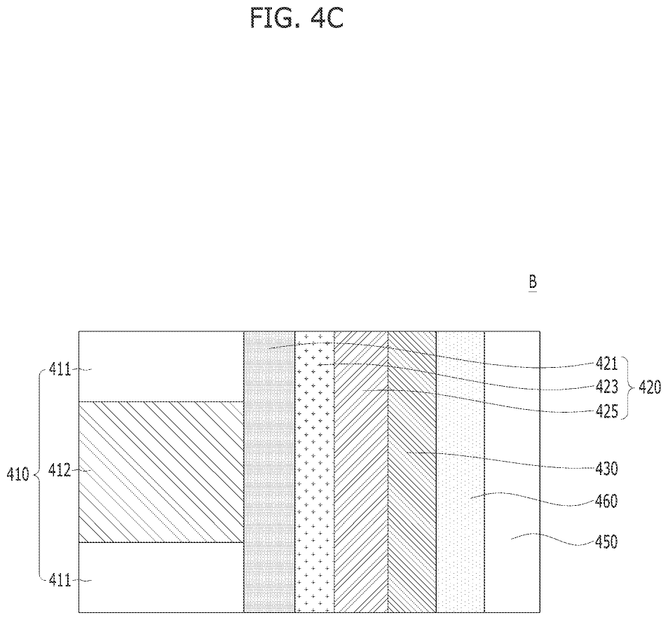

FIG. 4A to FIG. 4C are diagrams for describing a method of manufacturing a semiconductor device in accordance with an embodiment. FIG. 4B and FIG. 4C may be enlarged views of a region B in FIG. 4A. Hereinafter, content previously described is not repeated.

Referring to FIG. 4A, a stack 410A including first material layers 411 and second material layers 413 that are alternately stacked may be formed. Subsequently, an opening OP may be formed in the stack 410A. Subsequently, a channel layer 430 may be formed in the opening OP. Before the channel layer 430 is formed, a memory layer 420 may be formed.

A process of forming the memory layer 420 is described with reference to FIG. 4A and FIG. 4B. First, a blocking layer 421 may be formed in the opening OP. Subsequently, a data storage layer 423 may be formed in the blocking layer 421. Subsequently, a tunneling layer 425 may be formed in the data storage layer 423. Thus, the memory layer 420 including the blocking layer 421, the data storage layer 423, and the tunneling layer 425 may be formed. Subsequently, the channel layer 430 may be formed in the tunneling layer 425. The blocking layer 421 and the tunneling layer 425 may each include an insulating material such as an oxide or nitride, and the data storage layer 423 may include a floating gate, a polysilicon layer, a charge trap material, a nitride layer, a variable resistance material, or the like.

Subsequently, a diffusion barrier 460 may be formed. For example, the diffusion barrier 460 may be formed in the channel layer 430. The diffusion barrier 460 may prevent or reduce diffusion of metal included in a protective layer 480 into the channel layer 430. The diffusion barrier 460 may also prevent or reduce formation of a silicide layer due to a reaction between the protective layer 480 and the channel layer 430. The diffusion barrier 460 may include an insulating material such as an oxide or nitride. For example, the diffusion barrier 460 may include SiO₂, Si₃N₄, or the like.

Subsequently, the protective layer 480 may be formed in the diffusion barrier 460. First, a barrier layer 480A may be formed. The barrier layer 480A may be used to increase adhesion when a metal layer 480B is deposited. The barrier layer 480A may include metal or metal nitride. For example, the barrier layer 480A may include Ti, TiN, Ta, TaN, W, or WN, or a combination thereof. Subsequently, the metal layer 480B may be formed in the barrier layer 480A. The metal layer 480B may prevent or reduce damage to the memory layer 420 or the channel layer 430 during a passivation process. The metal layer 480B may include metal such as tungsten. Thus, the protective layer 480 including the barrier layer 480A and the metal layer 480B may be formed.

Subsequently, the passivation process may be performed. A halogen element may be diffused into at least one of the channel layer 430 and the memory layer 420. For example, a halogen element may be diffused into the channel layer 430 through the protective layer 480 and the diffusion barrier 460. Accordingly, at least one of the channel layer 430, an interface between the channel layer 430 and the memory layer 420, and the memory layer 420 may include a halogen element. For example, the channel layer 430 may include a halogen element at a first concentration, and the interface between the memory layer 420 and the channel layer 430 may include a halogen element at a second concentration higher than the first concentration.

Heat treatment may be performed simultaneously with or after the passivation process. When the heat treatment is performed, a halogen element may be diffused more rapidly or a greater amount of a halogen element may be diffused into the channel layer 430 and the memory layer 420.

Referring to FIG. 4C, an insulating core 450 may be formed. First, the protective layer 480 may be removed. For example, the protective layer 480 may be removed through a cleaning process using a sulfur peroxide mixture (SPM). Subsequently, the insulating core 450 may be formed in the opening OP. In such a case, the diffusion barrier 460 may remain without being removed. Subsequently, the second material layers 413 may be replaced with third material layers 412. Thus, a gate structure 410 including the first material layers 411 and the third material layers 412 that are alternately stacked may be formed.

According to the process described above, the diffusion barrier 460 and the protective layer 480 may be formed in the channel layer 430. The diffusion barrier 460 may prevent or reduce diffusion of metal included in the protective layer 480 into the channel layer 430. The diffusion barrier 460 may also prevent formation of a silicide layer due to a reaction between the protective layer 480 and the channel layer 430. The protective layer 480 may prevent or reduce damage to the channel layer 430 that occurs when a halogen element is diffused.

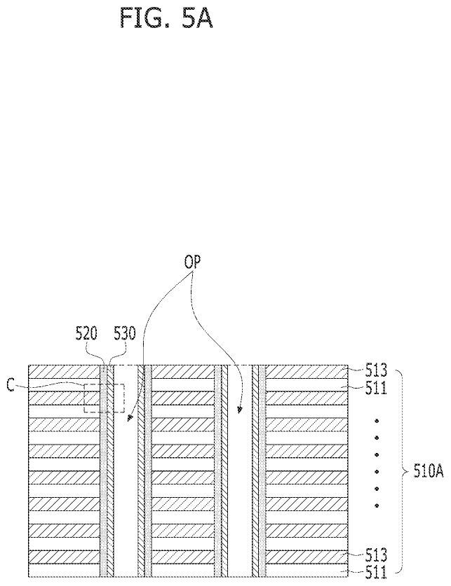

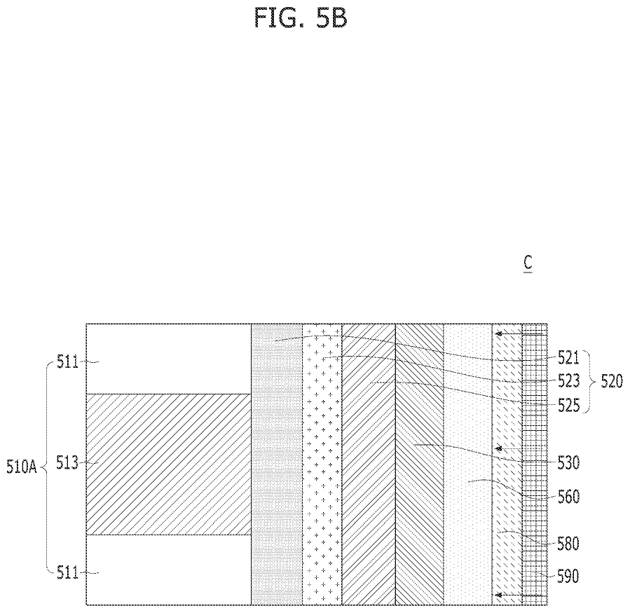

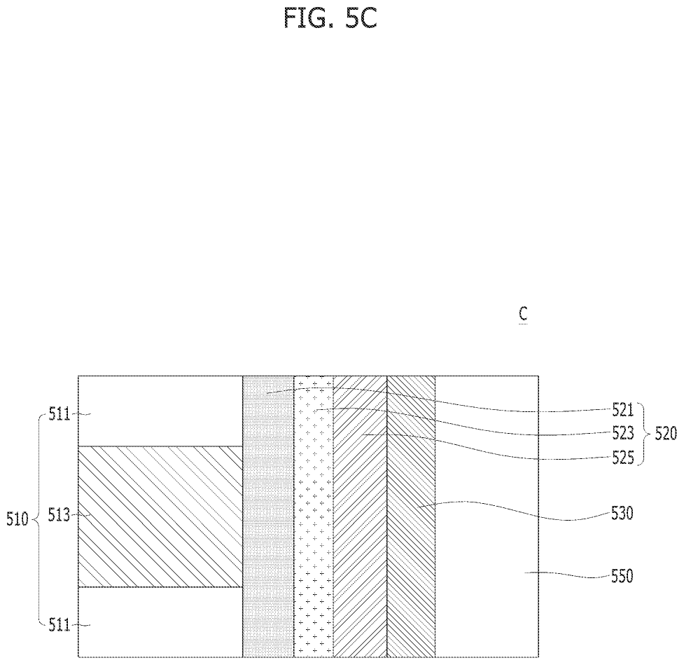

FIG. 5A to FIG. 5C are diagrams for describing a method of manufacturing a semiconductor device in accordance with an embodiment. FIG. 5B and FIG. 5C may be enlarged views of a region C in FIG. 5A. Hereinafter, content previously described is not repeated.

Referring to FIG. 5A and FIG. 5B, a stack 510A including first material layers 511 and second material layers 513 that are alternately stacked may be formed. Subsequently, at least one opening OP may be formed in the stack 510A. Subsequently, a memory layer 520 may be formed in the opening OP. The memory layer 520 may include a blocking layer 521, a data storage layer 523, and a tunneling layer 525. Subsequently, a channel layer 530 may be formed in the memory layer 520.

A protective layer 580 including metal may be formed in the channel layer 530. The protective layer 580 may prevent or reduce damage to the channel layer 530 and the memory layer 520. Before the protective layer 580 is formed, a diffusion barrier 560 may be formed in the channel layer 530. The diffusion barrier 580 may prevent or reduce diffusion of the metal included in the protective layer 580 into the channel layer 530 and the memory layer 520.

Subsequently, a passivation process may be performed. A passivation gas may be supplied through the opening OP. A passivation layer 590 may be formed in the opening OP. For example, the passivation layer 590 may be formed by a reaction between a passivation material and the protective layer 580 or the channel layer 530. The passivation layer 590 may include metal or silicon, or a combination thereof. For example, the passivation layer 590 may be a metal layer including a halogen element or a silicon layer including a halogen element.

When the passivation layer 590 is formed, a halogen element may be uniformly diffused into the channel layer 530 or the memory layer 520. When supplied in the form of a gas including a passivation material, the passivation material may be non-uniformly supplied within the opening OP having a large aspect ratio. A relatively smaller amount of passivation material may be supplied to a lower portion of the opening OP than an upper portion thereof, and a relatively small amount of halogen element may be diffused into the lower portion of the opening OP. Unlike this, when the passivation layer 590 is formed, the passivation layer 590 may be formed up to the lower portion of the opening OP, and thus the halogen element may be uniformly supplied to the upper portion and the lower portion of the opening OP. Accordingly, the halogen element may be uniformly diffused into an upper portion and a lower portion of the channel layer 530 or an upper portion and a lower portion of the memory layer 520. The passivation layer 590 may include metal or silicon, or a combination thereof.

Heat treatment may be performed after the passivation layer 590 is formed. For example, the passivation layer 590, the channel layer 530, and the memory layer 520 may be heat-treated. In such a case, a halogen element may be diffused more quickly or a greater amount of a halogen element may be diffused into the channel layer 530 and the memory layer 520 from the passivation layer 590.

Referring to FIG. 5C, an insulating core 550 may be formed. First, the passivation layer 590 may be removed. Subsequently, the protective layer 580 may be removed. Subsequently, the diffusion barrier 560 may be etched and removed. For example, the diffusion barrier 560 may be etched and removed by NH₄OH, HCl, H₂O₂, or H₃SO₄. Subsequently, the insulating core 550 may be formed in the opening OP. Subsequently, the second material layers 513 may be replaced with third material layers 512. Thus, a gate structure 510 including the first material layers 511 and the third material layers 512 that are alternately stacked may be formed.

The present specification has described an example in which the passivation barrier 580 and the diffusion barrier 560 are removed; however, the diffusion barrier 560 may remain without being removed.

According to the process described above, the passivation layer 590 may be formed. The passivation layer 590 may uniformly diffuse a halogen element into the channel layer 530 or the memory layer 520. Accordingly, the upper portion and the lower portion of the channel layer 530, the upper portion and the lower portion of the memory layer 520, and the upper portion and the lower portion of the interface between the channel layer 530 and the memory layer 520 may each include a halogen element at a uniform concentration.

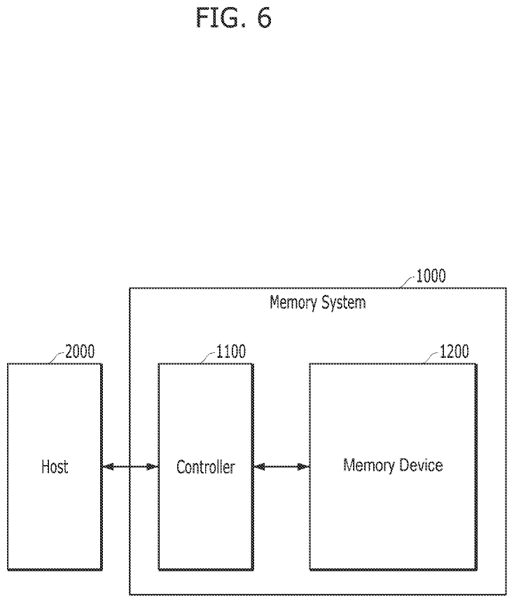

FIG. 6 is a diagram for describing a memory system in accordance with an embodiment.

Referring to FIG. 6, a memory system Memory System 1000 may include a memory device Memory Device 1200 that stores data and a controller Controller 1100 that communicates between the Memory Device 1200 and a host Host 2000.

The Host 2000 may be a device or system that stores data in the Memory System 1000 or retrieves data from the Memory System 1000. The Host 2000 may generate requests for various operations and output the generated requests to the Memory System 1000. The requests may include a program request for a program operation, a read request for a read operation, an erase request for an erase operation, and the like. The Host 2000 may communicate with the Memory System 1000 through various interfaces such as peripheral component interconnect express (PCIe), advanced technology attachment (ATA), serial ATA (SATA), parallel ATA (PATA), serial attached SCSI (SAS), non-volatile memory express (NVMe), universal serial bus (USB), multi-media card (MMC), enhanced small disk interface (ESDI), and integrated drive electronics (IDE).

The Host 2000 may include at least one of a computer, a portable digital device, a tablet, a digital camera, a digital audio player, a television, a wireless communication device, and a cellular phone; however, examples of the present disclosure are not limited thereto.

The Controller 1100 may control overall operations of the Memory System 1000. The Controller 1100 may control the Memory Device 1200 according to a request of the Host 2000. The Controller 1100 may control the Memory Device 1200 so that a program operation, a read operation, an erase operation, and the like may be performed according to a request of the Host 2000. Alternatively, the Controller 1100 may perform a background operation and the like for improving performance of the Memory System 1000 even without a request from the Host 2000.

The Controller 1100 may transmit a control signal and a data signal to the Memory Device 1200 in order to control the operation of the Memory Device 1200. The control signal and the data signal may be transmitted to the Memory Device 1200 through different input/output lines. The data signal may include a command, an address, or data. The control signal may be used to distinguish a section in which the data signal is input.

The Memory Device 1200 may perform a program operation, a read operation, an erase operation, and the like under the control of the Controller 1100. The Memory Device 1200 may be implemented as a volatile memory device that loses data stored therein when power is off or a non-volatile memory device that maintains data stored therein even though power is off. The Memory Device 1200 may be a semiconductor device having the structure described above with reference to FIG. 1A to FIG. 1E or FIG. 2. The Memory Device 1200 may be a semiconductor device manufactured by the manufacturing method described above with reference to FIG. 3A to FIG. 3D, FIG. 4A to FIG. 4C, or FIG. 5A to FIG. 5C. As an example, a semiconductor device may include: a gate structure including conductive layers and insulating layers that are alternately stacked; a channel layer located in the gate structure; a silicide layer located in the channel layer; and a memory layer surrounding the channel layer, and at least one of the channel layer, the silicide layer, and the memory layer may include a halogen element.

Although some embodiments according to the technical idea of the present disclosure have been described above with reference to the accompanying drawings, this is only for explaining the embodiments according to the concept of the present disclosure, and the present disclosure is not limited to the above embodiments. Various types of substitutions, modifications, and/or changes for the embodiments may be made by those skilled in the art, to which the present disclosure pertains, without departing from the technical idea of the present disclosure defined in the following claims, and it should be construed that these substitutions, modifications, and/or changes belong to the scope of the present disclosure.

What is claimed is:

1. A semiconductor device comprising:
a gate structure including insulating layers and conductive layers that are alternately stacked;
a channel layer located in the gate structure;
a silicide layer located in the channel layer; and
a memory layer surrounding the channel layer,
wherein at least one of the channel layer, the silicide layer, and the memory layer includes a halogen element.

2. The semiconductor device of claim 1, wherein the channel layer includes the halogen element at a first concentration, and an interface between the channel layer and the memory layer includes the halogen element at a second concentration higher than the first concentration.

3. The semiconductor device of claim 1, wherein the channel layer comprises:
a first portion whose concentration of the halogen element increases as the first portion becomes closer to the memory layer; and
a second portion whose concentration of the halogen element increases as the second portion becomes closer to the silicide layer.

4. The semiconductor device of claim 3, wherein the first portion is located closer to the memory layer than the second portion.

5. The semiconductor device of claim 1, wherein the halogen element includes at least one of fluorine (F) and chlorine (Cl).

6. The semiconductor device of claim 1, wherein the halogen element is located at an interface between the channel layer and the memory layer.

7. The semiconductor device of claim 1, wherein the halogen element is located at an interface between the channel layer and the silicide layer.

8. The semiconductor device of claim 1, wherein the memory layer comprises:
a tunneling layer surrounding the channel layer;
a data storage layer surrounding the tunneling layer; and
a blocking layer surrounding the data storage layer,
wherein at least one of the tunneling layer, the data storage layer, and the blocking layer includes the halogen element.

9. The semiconductor device of claim 8, wherein the tunneling layer includes the halogen element at a third concentration, and an interface between the tunneling layer and the channel layer includes the halogen element at a second concentration higher than the third concentration.

10. The semiconductor device of claim 1, further comprising:
an insulating core located in the silicide layer.

11. A semiconductor device comprising:
a gate structure including insulating layers and conductive layers that are alternately stacked;
a channel layer located in the gate structure and including a first halogen element at a first concentration;
a memory layer surrounding the channel layer; and
an insulating core located in the channel layer,
wherein an interface between the channel layer and the memory layer includes a second halogen element at a second concentration higher than the first concentration.

12. The semiconductor device of claim 11, further comprising:
a silicide layer located between the channel layer and the insulating core.

13. The semiconductor device of claim 11, further comprising:
a diffusion barrier located between the channel layer and the insulating core.

14. The semiconductor device of claim 13, wherein the diffusion barrier includes at least one of an oxide and nitride.

15. The semiconductor device of claim 11, wherein the first halogen element and the second halogen element are substantially same or different, the first halogen element or the second halogen element includes at least one of fluorine (F) and chlorine (Cl).

16. A method of manufacturing a semiconductor device, the method comprising:
forming a stack including first material layers and second material layers that are alternately stacked;
forming an opening in the stack;
forming a memory layer in the opening;
forming a channel layer in the memory layer;
forming a passivation layer including a halogen element in the channel layer; and
diffusing the halogen element into at least one of the memory layer and the channel layer from the passivation layer.

17. The method of claim 16, wherein the halogen element includes at least one of fluorine (F) and chlorine (Cl).

18. The method of claim 16, wherein the channel layer includes the halogen element at a first concentration, and an interface between the channel layer and the memory layer includes the halogen element at a second concentration higher than the first concentration.

19. The method of claim 16, wherein the passivation layer includes at least one of metal and silicon.

20. The method of claim 16, further comprising:
before forming the passivation layer, forming a protective layer including metal in the channel layer.

21. The method of claim 20, further comprising:
forming a silicide layer at an interface between the channel layer and the protective layer.

22. The method of claim 21, wherein, in the diffusing of the halogen element, the halogen element is diffused through the protective layer and the silicide layer.

23. The method of claim 21, further comprising:
before forming the protective layer, forming a diffusion barrier in the channel layer.

24. The method of claim 23, wherein the diffusion barrier prevents the metal included in the protective layer from being diffused into the channel layer.

25. The method of claim 21, further comprising:
removing the passivation layer; and
removing the protective layer.

26. The method of claim 16, further comprising:
forming an insulating core in the opening.

27. The method of claim 16, further comprising:
heat-treating the passivation layer, the channel layer, and the memory layer.

28. The method of claim 16, wherein forming the memory layer comprises:
forming a blocking layer in the opening;
forming a data storage layer in the blocking layer; and
forming a tunneling layer in the data storage layer.

29. A method of manufacturing a semiconductor device, the method comprising:
forming a stack including first material layers and second material layers that are alternately stacked;
forming an opening in the stack;
forming a channel layer in the opening;
forming a diffusion barrier in the channel layer;
forming a protective layer in the diffusion barrier;
diffusing a halogen element into the channel layer through the protective layer and the diffusion barrier;
removing the protective layer; and
forming an insulating core in the opening.

30. The method of claim 29, wherein the halogen element includes at least one of fluorine (F) and chlorine (Cl).

31. The method of claim 29, wherein forming the protective layer comprises:
forming a barrier layer; and
forming a metal layer in the barrier layer.

32. The method of claim 29, wherein the diffusion barrier includes at least one of an oxide and nitride.

33. The method of claim 29, wherein the diffusion barrier prevents metal included in the protective layer from being diffused into the channel layer.

34. The method of claim 29, further comprising:
before forming the channel layer, forming a memory layer.

35. The method of claim 34, wherein the channel layer includes the halogen element at a first concentration, and an interface between the channel layer and the memory layer includes the halogen element at a second concentration higher than the first concentration.
